(19) United States
(12) Patent Application Publication
(10) Pub. No.: US 2020/0016557 A1
(43) Pub. Date: Jan. 16, 2020

(54) SUPPLY LINE GUIDE FOR A VACUUM PROCESSING SYSTEM, USE OF A SUPPLY LINE GUIDE AND PROCESSING SYSTEM

(71) Applicants: Andre BRÜNING, Stockstadt (DE); Andreas SAUER, Großostheim (DE); Applied Materials, Inc., Santa Clara, CA (US)

(72) Inventors: Andre BRÜNING, Stockstadt (DE); Andreas SAUER, Großostheim (DE)

(21) Appl. No.: 15/764,311

(22) PCT Filed: Apr. 7, 2017
(86) PCT No.: PCT/EP2017/058373

§ 371 Date: Mar. 28, 2018

(51) Int. Cl. B01J 3/02; C23C 14/12; C23C 14/24; C23C 14/56; H01L 51/56

(52) U.S. Cl. CPC B01J 3/02; C23C 14/12; H01L 51/56; C23C 14/56; C23C 14/246

(57) ABSTRACT

A supply line guide for guiding a plurality of supply lines in a vacuum chamber of a processing system is described. The supply line guide includes a guiding arrangement including a plurality of connected elements, wherein the connected elements are angle-adjustable relative to each other. Further, the supply line guide includes a flexible tube provided around the guiding arrangement.

### TECHNICAL FIELD

Embodiments of the present disclosure relate to supply line guides for guiding supply lines through a vacuum environment. In particular, embodiments of the present disclosure relate to flexible supply line guides which are configured for guiding supply lines from an atmospheric environment through a vacuum chamber of a processing system to a movable processing device, particularly a material deposition source configured for OLED manufacturing.

### BACKGROUND

Organic evaporators are a tool for the production of organic light-emitting diodes (OLED). OLEDs are a special type of light-emitting diode in which the emissive layer comprises a thin-film of certain organic compounds. Organic light emitting diodes (OLEDs) are used in the manufacture of television screens, computer monitors, mobile phones, other hand-held devices, etc., for displaying information. OLEDs can also be used for general space illumination. The range of colors, brightness, and viewing angles possible with OLED displays is greater than that of traditional LCD displays, because OLED pixels directly emit light and do not involve a back light. Therefore, the energy consumption of OLED displays is considerably less than that of traditional LCD displays. Further, the fact that OLEDs can be manufactured onto flexible substrates results in further applications.

There are many challenges encountered in the manufacture of such display devices. In particular, one of the challenges is to provide moving processing devices in a vacuum environment with a continuous and reliable supply of media and power. For instance, conventional supply line guides show problems with respect to durability, particularly when the conventional supply line guides are connected to a moving device which may induce friction and rubbing between supply lines, which may eventually lead to damage and or failure of the supply lines.

Accordingly, there is a continuing demand for providing an improved supply line guide which overcomes at least some problems of conventional supply line guides.

### SUMMARY

In light of the above, a supply line guide for guiding a plurality of supply lines in a vacuum chamber of a processing system according to the independent claim 1 is provided. Further aspects, benefits, and features of the present disclosure are apparent from the claims, the description, and the accompanying drawings.

According to an aspect of the present disclosure, a supply line guide for guiding a plurality of supply lines in a vacuum chamber of a processing system is provided. The supply line guide includes a guiding arrangement including a plurality of connected elements, wherein the elements are angle-adjustable relative to each other. Further, the supply line guide includes a flexible tube provided around the guiding arrangement.

According to another aspect of the present disclosure, a supply line guide for guiding a plurality of supply lines in a vacuum chamber of a processing system is provided. The supply line guide includes a guiding arrangement including a plurality of connected ring-like elements which are connected to each other via centrally arranged joints such that the connected ring-like elements are angle-adjustable relative to each other. The connected ring-like elements provide a first guiding duct for a first group of supply lines. Further, the connected ring-like elements provide a second guiding duct for a second group of supply lines. The connected ring-like elements include a separation element separating a first volume of the first guiding duct from a second volume of the second guiding duct.

The supply line guide further includes a flexible metal tube provided around the guiding arrangement. The flexible tube provides a gas-tight casing for the plurality of supply lines. Further, the flexible tube provides a bending radius R_{b} of R_{b}≤500 mm.

Another aspect of the present disclosure pertains to a use of a supply line guide according to any embodiments described herein for guiding a plurality of supply lines to a movable device provided in a vacuum chamber of a processing system.

According to yet another aspect of the present disclosure, a processing system is provided. The processing system includes a vacuum processing chamber; a movable device provided in the vacuum processing chamber; and a supply line guide according to any embodiments described herein, wherein the supply line guide is connected to the movable device.

### BRIEF DESCRIPTION OF THE D WINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

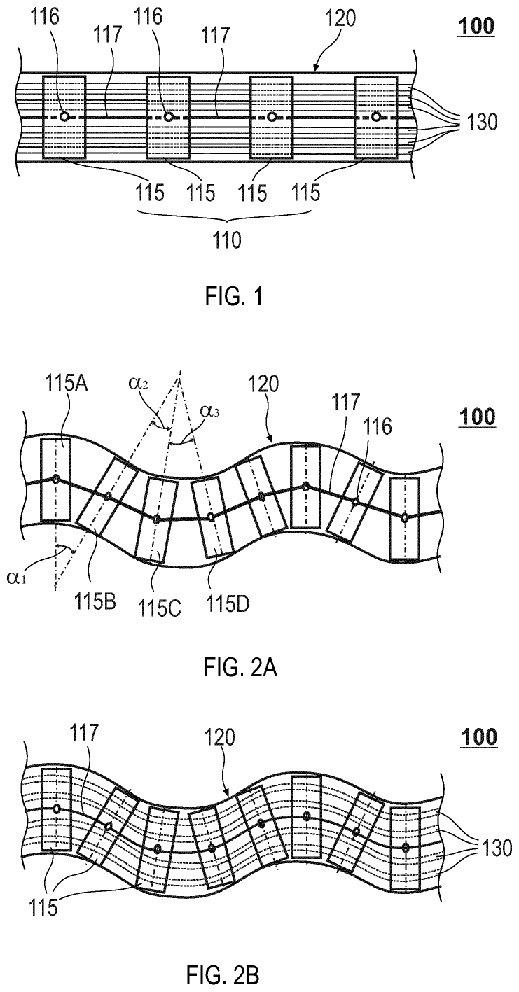

FIG. 1 shows a schematic cross-sectional side view of a section of a supply line guide according to embodiments described herein;

FIGS. 2A and 2B show schematic cross-sectional side views of a section of a supply line guide in a bended state according to embodiments described herein;

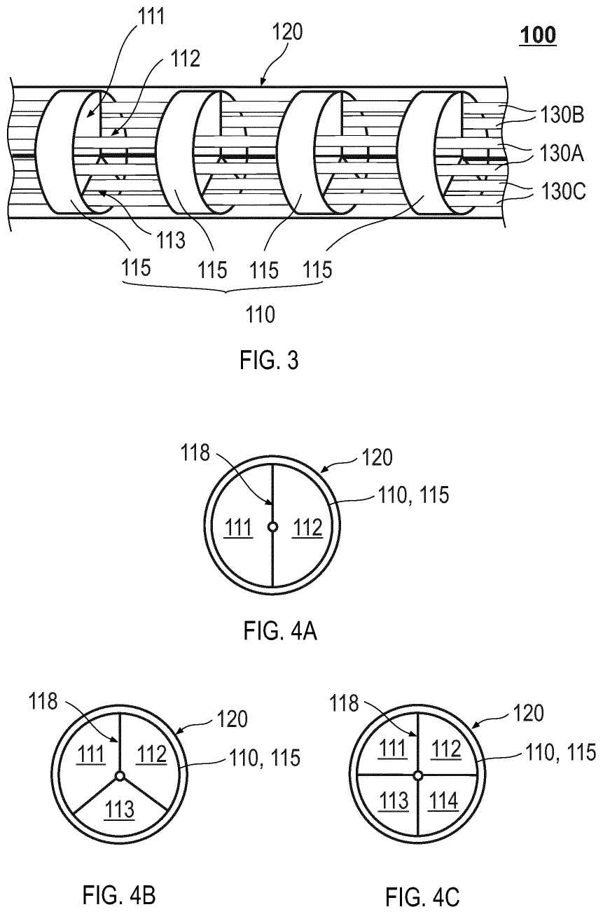

FIG. 3 shows a schematic cross-sectional side view of a section of a supply line guide according to embodiments described herein, wherein the connected elements of the guiding arrangement are schematically shown in an isometric view;

FIGS. 4A to 4C show schematic front views of a supply line guide according to embodiments described herein with different possible configurations of the elements of the guiding arrangement;

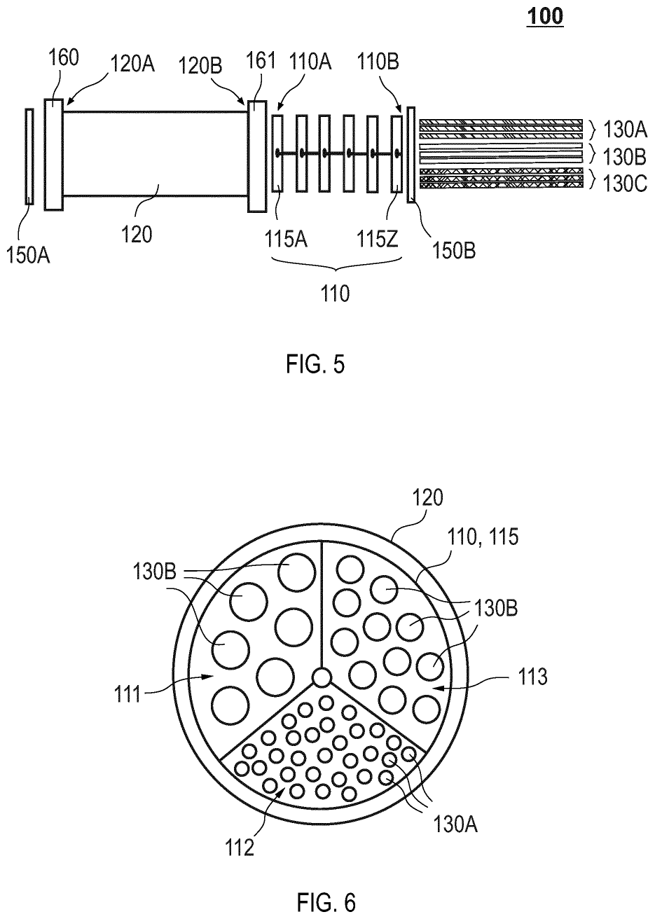

FIG. 5 shows a schematic exploded view of a supply line guide according to embodiments described herein;

FIG. 6 shows a schematic front view of a supply line guide according to embodiments described herein, wherein three separate guiding ducts are provided for three groups of supply lines;

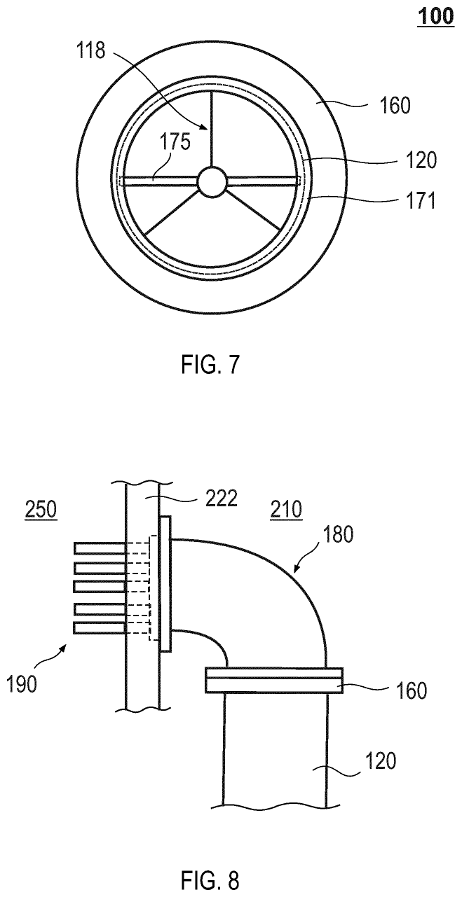

FIG. 7 shows a schematic front view of an end portion of a supply line guide according to embodiments described herein;

FIG. 8 shows a schematic side view of an end portion of a supply line guide according to further embodiments described herein;

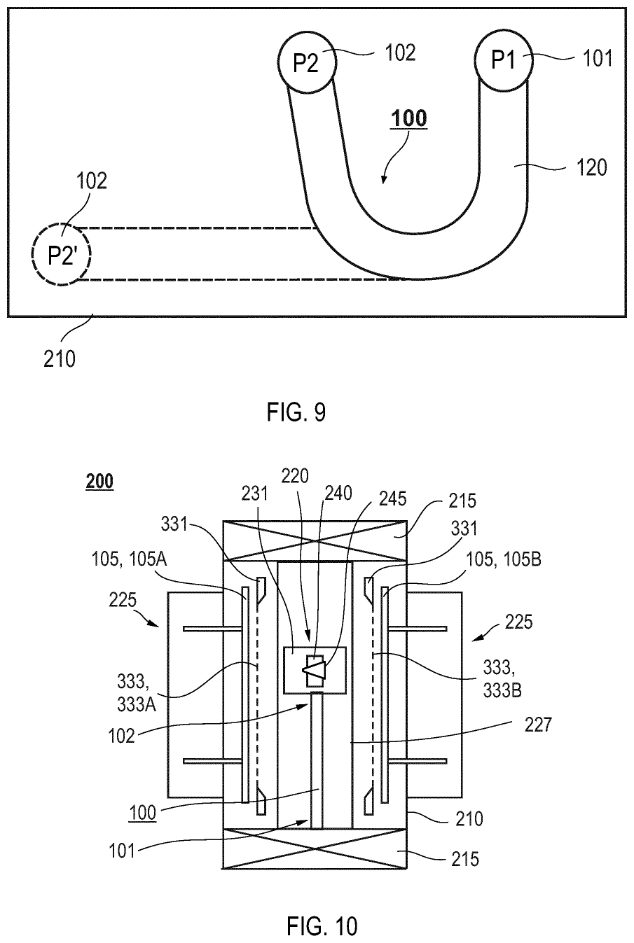

FIG. 9 shows a schematic side view of a supply line guide according to embodiments described herein in an exemplary first state (solid lines) and in an exemplary second state (dotted lines); and

FIG. 10 shows a schematic view of a processing system according to embodiments described herein including a supply line guide according to embodiments described herein.

### DETAILED DESCRIPTION OF EMBODIMENTS

Reference will now be made in detail to the various embodiments, one or more examples of which are illustrated in each figure. Each example is provided by way of explanation and is not meant as a limitation. For example, features illustrated or described as part of one embodiment can be used on or in conjunction with any other embodiment to yield yet a further embodiment. It is intended that the present disclosure includes such modifications and variations.

Within the following description of the drawings, the same reference numbers refer to the same or to similar components. Generally, only the differences with respect to the individual embodiments are described. Unless specified otherwise, the description of a part or aspect in one embodiment can apply to a corresponding part or aspect in another embodiment as well.

Before various embodiments of the present disclosure are described in more detail, some aspects with respect to some terms and expressions used herein are explained.

In the present disclosure, a “supply line guide” can be understood as a device which is configured for guiding at least one supply line. In particular, the supply line guide as described herein may be configured for guiding two or more groups of supply lines. For instance, a first group of supply lines can be configured for supplying power (i.e. electric power), a second group of supply lines can be configured for supplying a liquid medium (e.g. water, oil, etc.), and a third group of supply lines can be configured for supplying a gaseous medium (e.g. compressed air, inert gas, etc.). Accordingly, a group of supply lines may be understood as a group of supply lines in which all or the majority of supply lines provided in said group are configured to supply substantially the same (e.g. power, liquid, gas, etc.). Typically, the supply line guide as described herein is configured for guiding a plurality of supply lines in a vacuum chamber of a processing system. In particular, the supply line guide as described herein includes a guiding arrangement which is configured for guiding the plurality of supply lines and a flexible tube provided around the guiding arrangement.

In the present disclosure, a “vacuum chamber” is to be understood as a chamber configured for vacuum processing, particularly vacuum deposition. The term “vacuum”, as used herein, can be understood in the sense of a technical vacuum having a vacuum pressure of less than, for example, 10 mbar. Typically, the pressure in a vacuum chamber as described herein may be between 10⁻⁵ mbar and about 10⁻⁸ mbar, more typically between 10⁻⁵ mbar and 10⁻⁷ mbar, and even more typically between about 10⁻⁶ mbar and about 10⁻⁷ mbar. According to some embodiments, the pressure in the vacuum chamber may be considered to be either a partial pressure of an evaporated material within the vacuum chamber or the total pressure (which may approximately be the same when only the evaporated material is present as a component to be deposited in the vacuum chamber). In some embodiments, the total pressure in the vacuum chamber may range from about 10⁻⁴ mbar to about 10⁻⁷ mbar, especially in the case that a second component besides the evaporated material is present in the vacuum chamber (such as a gas or the like).

In the present disclosure, a “supply line” can be understood as a line which is configured for supplying power (e.g. electrical power) or a medium (e.g. a liquid material or gaseous material). Accordingly, a supply line configured for providing power may include one or more conductive wires. A supply line configured for providing a medium (e.g. a liquid material or gaseous material) may include one or more pipes or tubes.

In the present disclosure, a “guiding arrangement” can be understood as an arrangement which is configured for guiding a plurality of supply lines, particularly at least a first group of supply lines and a second group of supply lines. In particular, a guiding arrangement as described herein typically includes a plurality of elements which are connected to each other. Each of the plurality of elements can be configured for guiding supply lines as described herein. Accordingly, a guiding arrangement may be understood as a chain of a plurality of connected elements. Typically, the elements of the plurality of connected elements are configured to be angle-adjustable relative to each other. For example, a first element of the plurality of connected elements may have a different orientation than a second element of the plurality of elements and so on. Accordingly, the guiding arrangement may be a chain of connected elements which is configured such that the orientation of some or each of the elements differ.

In the present disclosure, a “plurality of connected elements” can be understood as a group of elements which are connected to each other along a line such that the group of elements form a chain of connected elements. In particular, as described herein, the chain of connected elements can be configured to be flexible, i.e. the individual elements of the plurality of connected elements may be angle-adjustable relative to each other such that the orientation of the individual elements may differ within the chain of elements.

Accordingly, in the present disclosure, the expression according to which “the elements are configured to be angle-adjustable relative to each other” can be understood in that the elements are connected to each other in such a way that the orientation of an individual element of the elements can differ with respect to another individual element of the elements. In other words, the orientation of the individual elements relative to each other can be changed, such that a flexible chain of a plurality of connected elements can be provided.

In the present disclosure, a “flexible tube” can be understood as a tube which is configured to be bendable, particularly without inducing plastic deformation. Accordingly, a flexible tube as described herein may be a tube which is configured to be elastic up to a certain degree of bending, e.g. for a bending radius R_{b} of R_{b}≥100 mm. For instance, the flexible tube may be a hose of flexible material. In this respect it is to be understood that a tube or hose of flexible material may provide for a bending radius R_{b} of R_{b}≥100 mm and that the flexible material provides for a certain degree of rigidity, e.g. such that a pressure difference of 1 bar between the interior and the exterior of the flexible hose or tube does not cause the flexible hose or tube to expand.

It is to be understood, that the bending radius (typically measured to an inside curvature) is the minimum radius one can bend a pipe, tube, sheet, cable or hose without kinking or damaging. The smaller the bending radius, the greater is the material flexibility (as the radius of curvature decreases, the curvature increases).

FIG. 1 shows a schematic cross-sectional side view of a section of supply line guide 100 according to embodiments described herein. In particular, for illustration purposes, FIG. 1 shows a schematic cross-sectional side view of a section of an embodiment of a supply line guide 100 in a non-bended state, and FIGS. 2A and 2B show schematic cross-sectional side views of a section of the supply line guide 100 in a bended state. For better illustration, FIG. 2A shows the supply line guide 100 without the supply lines and FIG. 2B shows the supply line guide in which the plurality of supply lines 130 are indicated by dotted lines.

According to embodiments which can be combined with any other embodiment described herein, the supply line guide 100 is configured for guiding a plurality of supply lines in a vacuum chamber of a processing system. As exemplarily shown in FIG. 1, the supply line guide 100 includes a guiding arrangement 110 including a plurality of connected elements 115. In particular, the plurality of connected elements can be configured for guiding a plurality of supply lines 130. For example, the individual elements of the plurality of connected elements 115 can be connected by connecting elements 117, as schematically shown in FIGS. 1, 2A and 2B. In particular, the connecting elements may include joints 116 or hinges which are configured for allowing a rotational movement. More specifically, with exemplary reference to FIG. 1, according to embodiments which can be combined with any other embodiments described herein, the plurality of connected elements 115 can be ring-like elements which are connected to each other via centrally arranged joints.

Accordingly, the individual elements of the plurality of elements may be connected to each other via joints or hinges, such that the elements are angle-adjustable relative to each other. For better understanding, FIG. 2A shows a bended configuration of the supply line guide in which the elements are adjusted relatively to each other at different angles. In particular, as exemplarily shown, a second element 115B may be oriented with respect to a first element 115A of the plurality of elements at a first angle α₁, a third element 115C may be oriented with respect to the second element 115B at a second angle α₁, a fourth element 115D may be oriented with respect to the third element 115C at a third angle α₁, and so forth.

Accordingly, it is to be understood that the joints 116 or hinges may be configured for providing at least one rotational degree of freedom, particularly at least two rotational degrees of freedom, more particularly three rotational degrees of freedom, i.e. a rotational degree of freedom around an x-coordinate, a rotational degree of freedom around a y-coordinate, and a rotational degree of freedom around a z-coordinate. Accordingly, as exemplarily shown in FIGS. 2A and 2B, the elements of the plurality of connected elements 115 are typically configured to be angle-adjustable relative to each other. Further, as exemplarily shown in FIGS. 1, 2A and 2B, according to embodiments described herein the supply line guide 100 typically includes a flexible tube 120 provided around the guiding arrangement 110.

Accordingly, by providing a supply line guide as described herein, particularly a supply line guide including a guiding arrangement being arranged within a flexible tube, an improved supply line guide is provided which is particularly well suited for guiding a plurality of supply lines in a vacuum chamber of a processing system. In particular, embodiments of the supply line guide as described herein are beneficially configured such that a pressure difference between the interior of the supply line guide and a vacuum provided around the supply line guide reduces or even eliminates a pressure-difference-induced expansion of the supply lines guided in the supply line guide. Accordingly, an expansion and/or a stretching of the supply lines guided by the supply line guide according to embodiments described herein can beneficially be reduced or even eliminated, such that a breakage or extreme stress of the supply lines can be avoided.

Further, embodiments of the supply line guide as described herein are in particular beneficial for providing supply lines to a moving device provided in a vacuum chamber, for example a vacuum deposition chamber of a vacuum processing system. For instance, the moving device can be a deposition source configured to be movable along a transportation track in order to deposit material onto a substrate. In particular, it is to be noted that embodiments as described herein provide for friction or rubbing protection between neighboring supply lines which may occur due to a bending of the supply line guide during a movement of the movable device to which the supply line guide is connected. For instance, a friction or rubbing of supply lines with the supply line guide casing, i.e. the flexible tube, is even avoided. In particular, if at all, in embodiments described herein a friction or sliding between the guiding arrangement and the flexible tube may occur.

Thus, compared to conventional supply line guides, embodiments of the supply line guide as described herein provide for a longer life, an easier installation process, less expansion of the supply line guide in a vacuum, easier installation of supply lines (e.g. hoses and cables), strain-relief for the supply lines guided in the supply line guide, as well as less sliding friction between different supply lines (e.g. between media hoses and electricity cables), as well as less sliding friction between the supply lines and the supply line guide casing, i.e. the flexible tube.

According to embodiments which can be combined with any other embodiments described herein, the flexible tube 120 provides a bending radius Rb of Rb≤500 mm. In other words, the flexible tube can be configured for providing a bending radius Rb of Rb≤500 mm. Further, the flexible tube 120 may be configured such that a pressure difference of 1 bar between the interior and the exterior of the flexible tube does not cause an expansion of the flexible tube, particularly in the radial direction. For instance, the flexible tube 120 may include a metal or metal alloy. In particular, the flexible tube 120 may include at least 50%, of metal or metal alloy, particularly at least 70% of metal or metal alloy, more particularly at least 90% of metal or metal alloy. According to an example, the flexible tube 120 may consist of a metal or metal alloy.

Accordingly, beneficially a supply line guide is provided which is configured such that a pressure difference between the interior of the supply line guide and a vacuum provided around the supply line guide reduces or even eliminates a pressure-difference-induced expansion of the supply lines guided in the supply line guide.

With exemplary reference to FIG. 3, according to embodiments which can be combined with any other embodiments described herein, the guiding arrangement 110 provides a first guiding duct 111 for a first group 130A of supply lines. In other words, the guiding arrangement can be configured for providing a first guiding duct for a first group of supply lines. Additionally, the guiding arrangement 110 can provide a second guiding duct 112 for guiding a second group 130B of supply lines. In other words, the guiding arrangement can be configured for providing a second guiding duct for guiding a second group of supply lines. Accordingly, beneficially the guiding arrangement 110 can be configured for avoiding contact between the first group of supply lines guided in the first guiding duct 111 and the second group of supply lines guided in the second guiding duct 112.

According to embodiments which can be combined with any other embodiments described herein, one or more further guiding ducts may be provided. For example, the guiding arrangement 110 can be configured for providing a third guiding duct 113 for guiding a third group of supply lines, as exemplarily shown in FIGS. 3 and 4B. Accordingly, the guiding arrangement 110 can be configured for avoiding contact between the third group of supply lines guided in the third guiding duct 113 and the first group of supply lines guided in the first guiding duct 111. It is to be understood that additionally, the guiding arrangement 110 can be configured for avoiding contact between the third group of supply lines guided in the third guiding duct 113 and the second group of supply lines guided in the second guiding duct 112.

Hence, beneficially separate compartments, i.e. guiding ducts, for different groups of supply lines can be provided. Such a configuration has the advantage that sliding friction between different groups of supply lines can be reduced or even eliminated. This may in particular be beneficial in the case that for example a first group of supply lines includes a metallic outer surface, e.g. a metallic supply line casing, and a second group of supply lines includes a polymeric outer surface, e.g. a polymeric supply line casing. Accordingly, it is to be understood that by providing separate guiding ducts for different groups of supply lines, sliding friction between supply line casings of different material can be avoided. Thus, damaging of a soft supply line casing (e.g. a polymeric supply line casing) by sliding friction between the soft supply line casing and a hard supply line casing (e.g. a metallic supply line casing) can be avoided. Accordingly, an improved supply line guide for providing supply lines to a moving device provided in a vacuum chamber can be provided.

FIGS. 4A to 4C show schematic front views of a supply line guide according to embodiments described herein with different possible configurations of the elements of the guiding arrangement. In particular, FIG. 4A shows a configuration in which the connected elements 115 of the guiding arrangement 110 provide a first guiding duct 111 for a first group of supply lines and a second guiding duct 112 for guiding a second group of supply lines. For instance, the guiding arrangement 110, particularly the connected elements 115, may include a separation element 118 separating a first volume of the first guiding duct 111 from a second volume of the second guiding duct 112, as exemplarily shown in FIG. 4A.

FIG. 4B shows an exemplary configuration in which the connected elements 115 of the guiding arrangement 110 are configured for providing a first guiding duct 111 for a first group of supply lines, for providing a second guiding duct 112 for guiding a second group of supply lines, and for providing a third guiding duct 113 for guiding a third group of supply lines. Accordingly, the connected elements 115 of the guiding arrangement 110 may include a separation element 118 configured for providing three separate volumes for each of the three guiding ducts as exemplarily shown in FIG. 4B. With exemplary reference to FIG. 4C, it is to be understood that the guiding arrangement 110 may be configured for providing three or more guiding ducts, for example four guiding ducts. Accordingly, the connected elements 115 of the guiding arrangement 110 may include a separation element 118 which is configured for providing a number of preselected separate volumes for a corresponding number of guiding ducts, e.g. a first guiding duct 111, a second guiding duct 112, a third guiding duct 113 and a fourth guiding duct 114 as exemplarily shown in FIG. 4C.

FIG. 5 shows a schematic exploded view of a supply line guide according to embodiments described herein. As exemplarily shown in FIG. 5, the supply line guide 100 may include a flexible tube 120 including a connecting flange. For instance, the flexible tube 120 may include a first connecting flange 160, e.g. for connecting the supply line guide to an interior wall of a vacuum chamber, and a second connecting flange 161, e.g. for connecting the supply line guide to a moving device provided inside the vacuum chamber. Further, the supply line guide 100 may include a first fixation element 150A configured for fixing a first end 110A of the guiding arrangement 110 to a first end 120A of the flexible tube 120. Additionally or alternatively, the supply line guide 100 may include a second fixation element 150B configured for fixing a second end 110B of the guiding arrangement 110 to a second end 120B of the flexible tube 120. Accordingly, according to embodiments which can be combined with any other embodiments described herein, a first end 110A of the guiding arrangement 110 can be connected to a first end 120A of the flexible tube 120 and/or a second end 110B of the guiding arrangement 110 can be connected to a second end 120B of the flexible tube 120.

More specifically, according to embodiments which can be combined with any other embodiments described herein, a position of a first element 115A of the plurality of connected elements can be fixed relative to a wall of the flexible tube 120, particularly at the first end 120A of the flexible tube 120. Accordingly, additionally or alternatively, a position of a last element 115Z of the plurality of connected elements can be fixed relative to a wall of the flexible tube 120.

FIG. 6 shows a schematic front view of a supply line guide according to embodiments described herein which can be combined with any other embodiments described herein, wherein three different groups of supply lines are provided in three separate guiding ducts. For instance, the first group 130A of supply lines provided in the first guiding duct 111 can be configured for supplying power (i.e. electric power). The second group 130B of supply lines provided in the second guiding duct 112 can be configured for supplying a liquid medium (e.g. water, oil, etc.) and the third group 130C of supply lines provided in the third guiding duct 113 can be configured for supplying a gaseous medium (e.g. compressed air, inert gas, etc.).

With exemplary reference to FIG. 7, according to embodiments which can be combined with any other embodiments described herein, the first element 115A of the plurality of connected elements can be fixed relative to the wall of the flexible tube 120 by a first inner centering element 171. Accordingly, although not explicitly shown, additionally or alternatively the last element of the plurality of connected elements can be fixed relative to the wall of the flexible tube by a second inner centering element. In particular, the first and or second inner centering element can be provided as a ring-like element at least partially provided in the interior of the flexible tube 120, as exemplarily shown for the first inner centering element 171 in FIG. 7. In particular, an inner centering element as described herein may be configured to provide a form fit with an inner end portion of the flexible tube as described herein.

Further, as exemplarily shown in FIG. 7, a pin 175 may be provided for fixing a position of the first element 115A of the plurality of connected elements in relation to the wall of the flexible tube. For instance, as exemplarily shown in

FIG. 7, the pin 175 may extend through a central portion of the separation element 118 provided in the interior of the first element 115A. Further, opposing ends of the pin 175 may extend into the inner centering element, as exemplarily indicated by dotted lines in FIG. 7.

As exemplarily described with reference to FIG. 5, according to embodiments which can be combined with any other embodiments described herein, the flexible tube 120 may include a connecting flange, e.g. a first connecting flange 160, configured for connecting the supply line guide 100 to a wall of a processing system or to a further connecting element. For instance, the further connecting element may be an elbow element 180, as exemplarily shown in FIG. 8. For instance, the elbow element 180 may be configured for connecting the supply line guide 100 to an opening provided in a wall 222 of a vacuum chamber 210 in order to provide the supply lines from an atmospheric environment 250, through the supply line guide to a movable device. Further, as exemplarily shown in FIG. 8, a strain relief element 190 may be provided, which is configured for reducing strain or tension due to bending of the supply lines fed through the opening in the wall 222 into the supply line guide 100. For example, the strain relief element 190 may include a plurality of pins which can be flexible for providing a strain relief. The strain relief element 190 may employ in connection with the elbow element 180 or without the elbow element.

Accordingly, embodiments described herein provide for an improved supply line guide 100 for guiding a plurality of supply lines in a vacuum chamber of a processing system. As an example, which can be combined with other configurations and embodiments described herein, the supply line guide 100 includes a guiding arrangement 110 including a plurality of connected ring-like elements. For example, the plurality of connected ring-like elements can be connected to each other via centrally arranged joints such that the connected ring-like elements are angle-adjustable relative to each other. Further, the connected ring-like elements may be configured for providing a first guiding duct 111 for guiding a first group of supply lines. Additionally, the connected ring-like elements may be configured for providing a second guiding duct 112 for guiding a second group of supply lines. Accordingly, the connected ring-like elements can be configured for avoiding contact between the first group of supply lines guided in the first guiding duct 111 and the second group of supply lines guided in the second guiding duct 112. Further, typically the supply line guide 100 includes a flexible metal tube provided around the guiding arrangement 110. In particular, beneficially the flexible tube is configured for providing a gas-tight casing for the plurality supply lines. Advantageously, the flexible tube 120 may be configured for providing a bending radius R_{b} of R_{b}≤500 mm.

According to an embodiment which can be combined with any other embodiments described herein, the guiding arrangement may be configured similar to a 3D e-chain, e.g. as used for 6-axis robots. Further, the guiding arrangement may include a material which is used for friction bearings, i.e. a material which is configured to be smooth in contact with other plastic- and metal parts and also resistant to stretching. Accordingly, beneficially embodiments of the supply line guide as described herein provide for an extension of life time of the supply lines (e.g. cables and hoses) and the flexible tube, which may also be referred to as a flexible metal hose.

FIG. 9 shows a schematic side view of a supply line guide according to embodiments described herein in an exemplary first state (solid lines) and in an exemplary second state (dotted lines). In particular, FIG. 9 shows that a first end 101 of the supply line guide 100 may have a fixed position P1, for example by being fixed to a wall of the vacuum chamber 210, and that a second end 102 of the supply line guide 100 may have a changeable position, e.g. from a first position P2 to a second position P2′, for example by being fixed to a movable device provided in the vacuum chamber 210.

In view of the embodiments described herein, it is to be understood that a supply line guide as described is well suited for being used in a vacuum chamber 210 of a processing system 200, as exemplarily shown in FIG. 10. Accordingly, another aspect to the present disclosure pertains to the use of a supply line guide according to any embodiments described herein for guiding a plurality of supply lines to a movable device provided in a vacuum chamber of a processing system.

FIG. 10 shows a schematic view of a processing system 200 according to embodiments described herein. Typically, the processing system 200 includes a vacuum chamber 210, a movable device 220 provided in the vacuum chamber 210, and a supply line guide 100 according to embodiments described herein. As exemplarily shown in FIG. 10, the supply line guide 100 is connected to the movable device 220. In particular, the first end 101 of the supply line guide 100 may be connected to the movable device 220 and the second end 102 of the supply line guide 100 may be connected to a wall of the vacuum chamber 210. For example, the movable device 220 may be a processing device such as a material deposition source. Further, the processing system 200 can include a substrate support 225 configured for supporting a substrate 105 during material deposition.

In particular, the movable device 220, e.g. a material deposition source, can be provided on a track or linear guide 227, as exemplarily shown in FIG. 10. The linear guide 227 may be configured for the translational movement of the material deposition source. Further, a drive for providing a translational movement of the material deposition source can be provided. In particular, a transportation apparatus for contactless transportation of the material deposition arrangement source may be provided in the vacuum chamber. As exemplarily shown in FIG. 10, the vacuum chamber 210 may have gate valves 215 via which the vacuum chamber can be connected to an adjacent routing module or an adjacent service module. Typically, the routing module is configured to transport the substrate to a further vacuum deposition chamber for further processing and the service module is configured for maintenance of the material deposition source. In particular, the gate valves allow for a vacuum seal to an adjacent vacuum chamber, e.g. of the adjacent routing module or the adjacent service module, and can be opened and closed for moving a substrate and/or a mask into or out of the vacuum processing system.

With exemplary reference to FIG. 10, according to embodiments which can be combined with any other embodiment described herein, two substrates, e.g. a first substrate 105A and a second substrate 105B, can be supported on respective transportation tracks within the vacuum chamber 210. Further, two tracks for providing masks 333 thereon can be provided. In particular, the tracks for transportation of a substrate carrier and/or a mask carrier may be provided with a further transportation apparatus for contactless transportation of the carriers.

Typically, coating of the substrates may include masking the substrates by respective masks, e.g. by an edge exclusion mask or by a shadow mask. According to typical embodiments, the masks, e.g. a first mask 333A corresponding to a first substrate 105A and a second mask 333B corresponding to a second substrate 105B, are provided in a mask frame 331 to hold the respective mask in a predetermined position, as exemplarily shown in FIG. 10.

As shown in FIG. 10, the linear guide 227 provides a direction of the translational movement of the movable device 220, particularly the deposition source. On both sides of the material deposition source, a mask 333, e.g. a first mask 333A for masking a first substrate 105A and second mask 333B for masking a second substrate 105B can be provided. The masks can extend essentially parallel to the direction of the translational movement of the deposition source. Further, the substrates at the opposing sides of the evaporation source can also extend essentially parallel to the direction of the translational movement.

With exemplary reference to FIG. 10, a source support 231 configured for the translational movement of the material deposition source along the linear guide 227 may be provided. Typically, the source support 231 supports a crucible 240 and a distribution assembly 245 provided over the evaporation crucible, as schematically shown in FIG. 10. Accordingly, a vapor generated in the evaporation crucible can move upwardly and out of the one or more outlets of the distribution assembly. Accordingly, the distribution assembly is configured for providing evaporated material, particularly a plume of evaporated organic material, from the distribution assembly 245 to the substrate 105. It is to be understood that FIG. 10 only shows a schematic representation of the supply line guide 100, and that the supply line guide 100 provided in the vacuum chamber 210 of the processing system 200 can have any configuration of the embodiments described herein, as exemplarily described with reference to FIGS. 1 to 9.

Accordingly, in view of the above, it is to be understood that embodiments as described herein provide for an improved supply line guide for guiding a plurality of supply lines to a moving device provided in a vacuum environment. In other words, embodiments described herein provide for an improved flexible media feed through for supplying media to a moving device in a vacuum. Further, it is to be understood that the supply line guide as described herein may not only be used for guiding supply lines to a deposition source as exemplarily described with respect to FIG. 10, but can also be used for guiding supply lines to any other movable device which needs a media supply such as electricity, pressurized air, water for cooling or others. In particular, embodiments as described herein provide for an improved solution for supplying media from an atmospheric environment through a vacuum environment over long distances to a movable device. For example, the movable device can be a movable shutter, a movable mask, a movable media arm, a movable substrate carrier or any other movable device which is to be supplied with supply power or media.

Further, it is to be understood that embodiments as described herein provide for a strain-relief for supply lines (e.g. cables and hoses) guided in the supply line guide which may occur due to stretching. Additionally, embodiments as described herein provide for friction or rubbing protection between neighboring supply lines which may occur due to a bending of the supply line guide during the movement of the movable device to which the supply line guide is connected. In particular, a stretch protection for supply lines, for instance metal hoses, can be provided. For instance, in conventional supply line guides, the supply lines are stretched due to the pressure difference between the inside of the supply line guide (e.g. having atmospheric conditions) and the outside of the supply line guide (e.g. having vacuum conditions). Such a stretching can substantially be avoided with embodiments as described herein.

Further, embodiments as described herein provide for improved solution in order to supply media to a movable device over long distances, wherein, due to the large moving range of the movable device, small bending radii may occur, particularly when the supply line guide is in a coiled or rolled-up state. Accordingly, embodiments as described herein beneficially provide for a longer life, an easier installation process, less expansion of the supply line guide in a vacuum, easier installation of supply lines (e.g. hoses and cables), strain-relief for the supply lines guided in the supply line guide, as well as less sliding friction between different supply lines (e.g. between media hoses and electricity cables).

While the foregoing is directed to embodiments of the disclosure, other and further embodiments of the disclosure may be devised without departing from the basic scope thereof, and the scope thereof is determined by the claims that follow.

In particular, this written description uses examples to disclose the disclosure, including the best mode, and also to enable any person skilled in the art to practice the described subject-matter, including making and using any devices or systems and performing any incorporated methods. While various specific embodiments have been disclosed in the foregoing, mutually non-exclusive features of the embodiments described above may be combined with each other. The patentable scope is defined by the claims, and other examples are intended to be within the scope of the claims if the claims have structural elements that do not differ from the literal language of the claims, or if the claims include equivalent structural elements with insubstantial differences from the literal language of the claims.

1. A supply line guide for guiding a plurality of supply lines in a vacuum chamber of a processing system, the supply line guide comprising:
a guiding arrangement including a plurality of connected elements, wherein the connected elements are angle-adjustable relative to each other: and
a flexible tube provided around the guiding arrangement.

2. The supply line guide according to claim 1, wherein the flexible tube provides a bending radius R_{b} of R_{b}≤500 mm.

3. The supply line guide according to claim 1, wherein the flexible tube includes a metal.

4. The supply line guide according to claim 1, wherein the guiding arrangement includes a first guiding duct for a first group of supply lines and a second guiding duct for guiding a second group of supply lines.

5. The supply line guide according to claim 4, wherein the guiding arrangement includes a separation element separating a first volume of the first guiding duct from a second volume of the second guiding duct.

6. The supply line guide according to claim 1, wherein the guiding arrangement includes a third guiding duct for guiding a third group of supply lines.

7. The supply line guide according to claim 6, wherein the guiding arrangement includes a separation element separating a first volume of the first guiding duct, a second volume of the second guiding duct and a third volume of a third guiding duct from each other.

8. The supply line guide according to claim 1, wherein a first end of the guiding arrangement is connected to a first end of the flexible tube, and wherein a second end of the guiding arrangement is connected to a second end of the flexible tube.

9. The supply line guide according to claim 1, wherein a position of a first element of the plurality of connected elements is fixed relative to a wall of the flexible tube.

10. The supply line guide according to claim 9, wherein the first element is fixed relative to the wall of the flexible tube by a first inner centering element.

11. The supply line guide according to claim 1, wherein the flexible tube comprises a connecting flange.

12. The supply line guide according to claim 1, wherein the plurality of connected elements are ring-like elements which are connected to each other via centrally arranged joints.

13. A supply line guide for guiding a plurality of supply lines in a vacuum chamber of a processing system, the supply line guide comprising:
a guiding arrangement including a plurality of connected ring-like elements which are connected to each other via centrally arranged joints such that the connected ring-like elements are angle-adjustable relative to each other, wherein the connected ring-like elements provide a first guiding duct for a first group of supply lines and provide a second guiding duct for a second group of supply lines, and wherein the connected ring-like elements include a separation element separating a first volume of the first guiding duct from a second volume of the second guiding duct; and
a flexible metal tube provided around the guiding arrangement, wherein the flexible tube provides a gas-tight casing for the plurality supply lines, and wherein the flexible tube provides a bending radius R_{b} of R_{b}≤500 mm.

14. Use of a supply line guide for guiding a plurality of supply lines to a movable device provided in a vacuum chamber of a processing system, the supply line guide comprising:
a guiding arrangement including a plurality of connected elements, wherein the connected elements are angle-adjustable relative to each other; and
a flexible tube provided around the guiding arrangement.

15. A processing system comprising:
a vacuum chamber;
a movable device provided in the vacuum chamber; and
a supply line guide connected to the movable device, the supply line guide comprising:
a guiding arrangement including a plurality of connected elements, wherein the connected elements are angle-adjustable relative to each other; and
a flexible tube provided around the guiding arrangement.

16. The supply line guide according to claim 4, wherein the guiding arrangement includes a third guiding duct for guiding a third group of supply lines.

17. The supply line guide according to claim 5, wherein the guiding arrangement includes a third guiding duct for guiding a third group of supply lines.

18. The supply line guide according to claim 1, wherein a position of a last element of the plurality of connected elements is fixed relative to a wall of the flexible tube.

19. The supply line guide according to claim 1, wherein a position of a first element of the plurality of connected elements is fixed relative to a wall of the flexible tube, and wherein a position of a last element of the plurality of connected elements is fixed relative to a wall of the flexible tube.

20. The supply line guide according to claim 18, wherein the last element is fixed relative to the wall of the flexible tube by a second inner centering element.
